(19) United States
(12) Patent Application Publication
(10) Pub. No.: US 2002/0038874 A1
(43) Pub. Date: Apr. 4, 2002

(54) Hetero-bipolar transistor and method of manufacture thereof

(75) Inventor: Katsumi Egashira, Fuchu-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: KABUSHIKI KAISHA TOSHIBA, Minato-ku (JP)

(21) Appl. No.: 09/964,461

(22) Filed: Sep. 28, 2001

(30) Foreign Application Priority Data
Sep. 29, 2000 (JP) 2000-301440

(51) Int. Cl. H01L 31/0328

(52) U.S. Cl. 257/197; 257/196; 257/565; 257/591

(57) ABSTRACT

A hetero-bipolar transistor comprises: a first-conductive-type Si semiconductor substrate layer; a first Si₁₋ₓGeₓ layer (0<x<1) formed on the first-conductive-type Si semiconductor substrate, the first Si₁₋ₓGeₓ layer being doped with a first-conductive-type impurity; a second Si₁₋ₓGeₓ layer formed on the first Si₁₋ₓGeₓ layer, the second Si₁₋ₓGeₓ layer being doped with a second-conductive-type impurity; and a Si layer formed on the second Si₁₋ₓGeₓ layer, the Si layer being doped with the first-conductive-type impurity by a concentration higher than that of the second-conductive-type impurity. A method of manufacturing the hetero-bipolar transistor, comprises: preparing a substrate having a first-conductive-type Si semiconductor substrate layer and a first Si₁₋ₓGeₓ layer formed on the first-conductive-type Si semiconductor substrate layer, the first Si₁₋ₓGeₓ layer doped with a first-conductive-type impurity approximately evenly in a depth direction thereof; forming a second Si₁₋ₓGeₓ layer and a Si layer on the first Si₁₋ₓGeₓ layer in a laminated manner, the second Si₁₋ₓGeₓ layer being doped with a second-conductive-type impurity; forming an insulating film having an opening on the Si layer; and doping the first-conductive-type impurity to the Si layer through the opening by a concentration higher than that of the second-conductive-type impurity.

### CROSS REFERENCE TO RELATED APPLICATION

This application is based upon and claims the benefit of priority from the prior Japanese Patent Application No. 2000-301440, filed on Sep. 29, 2000; the entire contents of which are incorporated herein by reference.

### BACKGROUND OF THE INVENTION

1. Field of the Invention

The present invention relates to a semiconductor device and a method of manufacture thereof, more specifically to a hetero-bipolar transistor (HBT) using a narrow band-gap material for a base region.

2. Description of the Related Art

Recent years, there has been developed a Si/SiGe hetero-bipolar transistor (HBT) using Si layers for an emitter region and a collector region and using a Si₁₋ₓGeₓ layer (0<x<1) with a band gap narrower than that of Si of the base region. Since the Si/SiGe hetero-bipolar transistor (HBT) is inexpensive and easy to be applied to a Si device, various kinds of usage thereof have been studied for optical communications, radio equipment and the like.

FIG. 1 is a sectional view schematically showing a structure of a conventional Si/SiGe-HBT of a general npn-type. As shown in FIG. 1, on a buried n⁺-type Si layer 100, an n⁻-type Si epitaxial layer 120 doped with phosphorous (P) as an n-type impurity is formed. On the periphery of sidewalls of the n⁻-type Si epitaxial layer 120, a buried insulating film 130 is formed so as to define a transistor-forming region. On an exposed surface of the n⁻-type Si epitaxial layer 120, a SiGe/Si epitaxial layer 140 is formed, in which the Si₁₋ₓGeₓ layer (hereinafter referred to as a “SiGe layer”) and the Si layer are continuously subjected to epitaxial growth by use of a selective growth method. Note that, the SiGe/Si epitaxial layer 140 includes a layer without an impurity doped thereto (an undoped layer) in a lower layer portion thereof, and boron (B) as a p-type impurity is doped on an upper layer thereof, thus a layer structure thereof is formed. A surface of the SiGe/Si epitaxial layer 140 is coated with an oxidation film 150 having an opening. This opening is buried with an n⁺-type polycrystal Si layer 160 that is doped with arsenic (As) as an n-type impurity by a high concentration. This As is thermally diffused into a Si layer portion as an upper layer of the SiGe/Si epitaxial layer 140 from the n⁺-type polycrystal Si layer 160 through the opening by a high concentration. A region into which this As is diffused forms an n-type Si epitaxial region 170.

During operation of the Si/SiGe hetero-bipolar transistor, the n-type Si epitaxial region 170 becomes the emitter region, the SiGe/Si epitaxial layer 140 in the periphery thereof becomes the base region, and the n⁻-type Si epitaxial layer 120 thereunder and the n⁺-type Si layer 100 therebelow become the collector region.

In the Si/SiGe-HBT structure, the base region is formed of SiGe with a band gap narrower than that of Si of the emitter region. Therefore, a high-speed operation of the HBT is enabled by use of a potential barrier between the emitter and base regions. However, in order to secure a much better high-speed operation characteristic, the following are required: (1) optimization of a composition profile in a depth direction of the HBT, which includes the band gap, an impurity concentration and the like; and (2) improvement of crystallinity of the epitaxial layer.

FIG. 2 is a diagram showing the composition profile in the depth direction of the conventional Si/SiGe-HBT shown in FIG. 1. An axis of abscissas indicates the depth, and an axis of ordinates indicates the impurity concentration and a Ge concentration. As shown in FIG. 2, in the recent Si/SiGe-HBT, the Ge concentration is adjusted so as to be gradually increased from the emitter region to the collector region in the SiGe layer of the base region. Such an increase brings an effect of achieving an acceleration of carriers in the base region by an inclination of the band gap due to the concentration gradient of Ge.

Moreover, in a region deeper than the region where the Ge concentration is inclined, an undoped-SiGe layer with a certain Ge concentration and without an impurity doped thereto is formed. This is because a hetero interface between the SiGe layer and a Si substrate thereunder is not allowed to be formed in the base region. Specifically, if the hetero interface exists in a conduction band within the base region, a band offset is generated due to the existence of the hetero interface, and such a band barrier disturbs the carriers moving. The hetero interface is not allowed to be formed in order to prevent the situation as described above.

Incidentally, a junction surface between the base region and the emitter region (an E-B junction) is formed at a position where the concentration of As as an n-type impurity and the concentration of B as a p-type impurity intercross. Moreover, a junction surface between the base region and the collector region (a B-C junction) is formed at a position where the concentration of boron (B) that is being diffused from the base region into the undoped-SiGe layer and the concentration of phosphorous (P) that is being diffused from the Si substrate thereinto intercross. Therefore, a thickness of the base region is determined by the two junction surfaces of the E-B junction and the B-C junction.

In order to further accelerate the carrier action, it is desirable that the thickness of the base region is thinned more. However, as described above, the position of the B-C junction surface, which determines one end of the base region, is determined by two diffusion conditions: a diffusion condition for P from the collector region; and a diffusion condition for B from the base region. Therefore, both of the junction surfaces cannot be readily adjusted, and it is difficult to thin the thickness of the base region with good reproductivity.

Moreover, as apparent from FIG. 2, since the concentrations of both of the n-type and p-type impurities become low in the vicinity of the B-C junction surface, a depletion layer tends to expand, resulting in an increase of a junction capacitance to extend a carrier transit time, which is pointed out as a problem.

Meanwhile, on the hetero interface between the SiGe layer and the Si substrate, which remain within the collector region, a distortion thereof due to a difference between crystal lattice intervals of the layer and the substrate cannot be ignored, alternatively, a misfit transition generated so as to absorb the distortion cannot be ignored, which is pointed out as a problem.

As described above, the conventional Si/SiGe-HBT still has some subjects in the following points of: (1) optimization of the composition profile in the depth direction; and (2) formation of an epitaxial layer having good crystallinity with less distortion.

### BRIEF SUMMARY OF THE INVENTION

A semiconductor device according to an aspect of the present invention comprises: a first-conductive-type Si semiconductor substrate layer; a first Si₁₋ₓGeₓ layer (0<x<1) formed on the first-conductive-type Si semiconductor substrate, the first Si₁₋ₓGeₓ layer being doped with a first-conductive-type impurity approximately evenly in a depth direction thereof; a second Si₁₋ₓGeₓ layer formed on the first Si₁₋ₓGeₓ layer, the second Si₁₋ₓGeₓ layer being doped with a second-conductive-type impurity; and a Si layer formed on the second Si₁₋ₓGeₓ layer, the Si layer being doped with the first-conductive-type impurity by a concentration higher than that of the second-conductive-type impurity.

A method of manufacture of a semiconductor device according to another aspect of the present invention comprises: preparing a substrate having a first-conductive-type Si semiconductor substrate layer and a first Si₁₋ₓGeₓ layer formed on the first-conductive-type Si semiconductor substrate layer, the first Si₁₋ₓGeₓ layer doped with a first-conductive-type impurity approximately evenly in a depth direction thereof; forming a second Si₁₋ₓGeₓ layer and a Si layer on the first Si₁₋ₓGeₓ layer in a laminated manner, the second Si₁₋ₓGeₓ layer being doped with a second-conductive-type impurity; forming an insulating film having an opening on the Si layer; and doping the first-conductive-type impurity to the Si layer through the opening by a concentration higher than that of the second-conductive-type impurity.

### BRIEF DESCRIPTION OF THE DRAWINGS

FIG. 1 is a sectional view showing a structure of a conventional hetero-bipolar transistor.

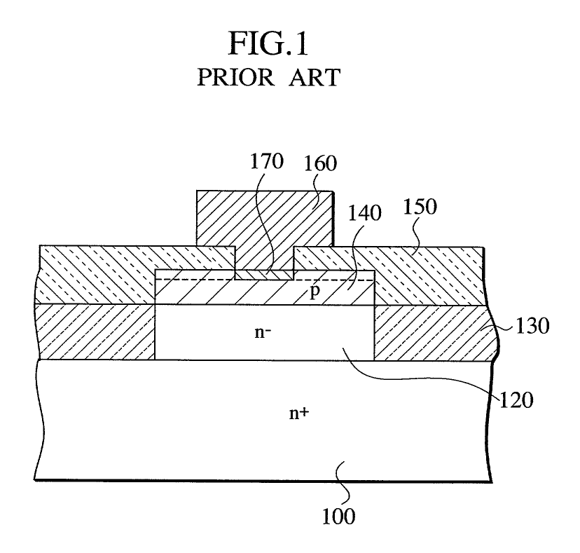

FIG. 2 is a diagram showing a composition distribution in a depth direction of the conventional hetero-bipolar transistor.

FIG. 3 is a sectional view showing a structure of a hetero-bipolar transistor according to a first embodiment of the present invention.

FIG. 4 is a diagram showing a composition distribution in a depth direction of the hetero-bipolar transistor according to the first embodiment of the present invention.

FIGS. 5A to 5E are sectional views for explaining respective steps of a method of manufacture of the hetero-bipolar transistor according to the first embodiment of the present invention.

FIG. 6 is a sectional view showing a structure of a hetero-bipolar transistor according to a second embodiment of the present invention.

FIGS. 7A to 7E are sectional views for explaining respective steps of a method of manufacture of the hetero-bipolar transistor according to the second embodiment of the present invention.

FIG. 8 is a sectional view showing a structure of a hetero-bipolar transistor according to a third embodiment of the present invention.

### DETAILED DESCRIPTION OF THE EMBODIMENTS

Hereinafter, description will be made for embodiments of the present invention with reference to the drawings.

### First Embodiment

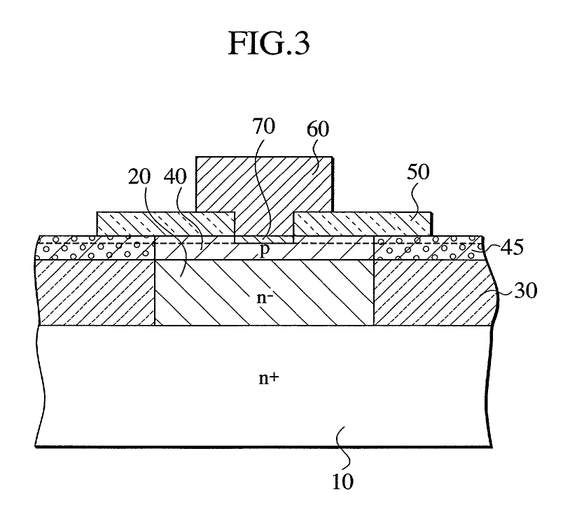

FIG. 3 is a sectional view showing a structure of a Si/SiGe-hetero-bipolar transistor (HBT) according to a first embodiment of the present invention. As shown in FIG. 3, in the Si/SiGe-HBT of this embodiment, instead of the conventional n⁻-type Si layer, a Si₁₋ₓGeₓ epitaxial layer doped with an n-type impurity (hereinafter referred to as an “n⁻-type SiGe epitaxial layer”) 20 is formed on an n⁺-type Si layer 10 (a Si semiconductor substrate layer). The periphery of a transistor-forming region is isolatedly insulated by a buried insulating film 30.

On the n⁻-type SiGe epitaxial layer 20, a p-type Si/SiGe epitaxial layer 40 is formed, in which an upper layer is Si and a lower layer is SiGe. A dotted line in FIG. 3 indicates a boundary between Si and SiGe. Moreover, a p-type polycrystal Si/SiGe layer 45 is formed on the buried insulating film 30.

The p-type Si/SiGe epitaxial layer 40 is covered with an oxidation film 50 having an opening, an n⁺-type polycrystal Si layer 60 doped with the n-type impurity by a high concentration is formed so as to bury the opening, and the n-type impurity is thermally diffused from the n⁺-type polycrystal Si layer 60 to the Si layer portion of the p-type Si/SiGe epitaxial layer 40 by a higher concentration than that of the p-type impurity, thus an n-type Si epitaxial region 70 is formed as an emitter region.

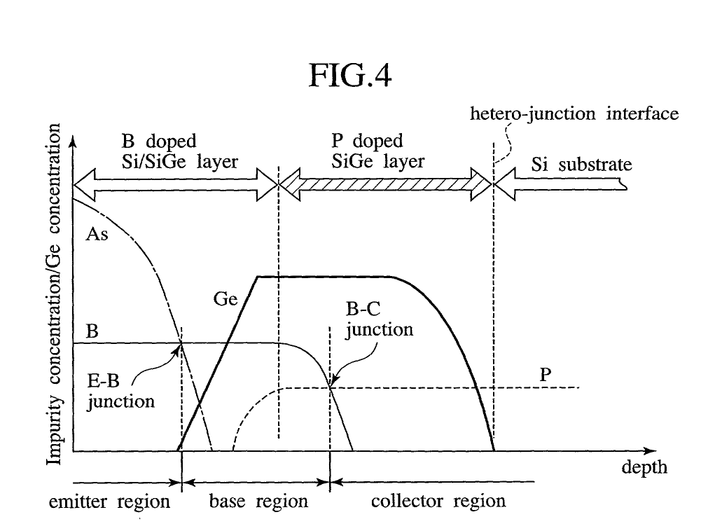

FIG. 4 is a diagram showing a composition profile in a depth direction of the Si/SiGe-HBT according to the first embodiment. An axis of abscissas indicates a depth, and an axis of ordinates indicates an impurity concentration and a Ge concentration.

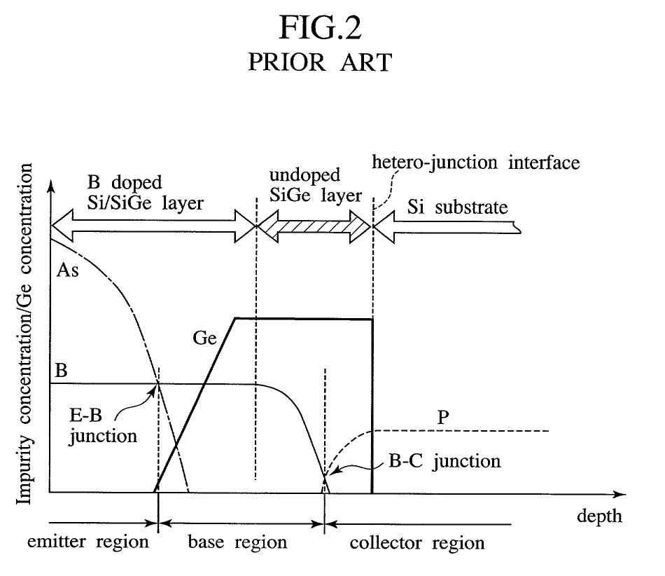

As apparent in comparison with the composition profile in the depth direction of the conventional Si/SiGe-HBT shown in FIG. 2, in the first embodiment, formed on a collector region is a P-doped SiGe layer doped with phosphorous (P) as an n-type impurity in the depth direction by an approximately even concentration (the n⁻-type SiGe epitaxial layer 20 in FIG. 3). On the n⁻-type SiGe epitaxial layer 20, formed is a B-doped Si/SiGe layer doped with boron as a p-type impurity (the p-type Si/SiGe epitaxial layer 40 in FIG. 3).

The impurities B and P doped in the layers adjacent to each other generate impurity diffusion, mutually. Accordingly, base/collector junction (B-C junction) is formed at a position where the concentrations of the impurities B and P intercross with each other. Here, in the HBT of the first embodiment, P is doped by an approximately even concentration in the depth direction, furthermore, B is doped in the Si/SiGe layer by a higher concentration than that of P. Therefore, the B-C junction position is determined mainly by a diffusion condition of B. As described above, the B-C junction position can be adjusted by use of adjustment factors less than the conventional. Therefore, a width of a base region can be adjusted to be narrower, thus enabling an acceleration of carriers.

Heretofore, both of the B concentration and the P concentration at the B-C junction position have been low, and expansion of the depletion layer in the junction portion has not been able to be suppressed. On the other hand, in the Si/SiGe-HBT according to the first embodiment, since the B concentration and the P concentration at the B-C junction position can be maintained to be relatively high, the expansion of the depletion layer can be suppressed. Consequently, a waste of a carrier transit time due to the depletion layer can be suppressed.

Moreover, in the Si/SiGe-HBT according to the first embodiment, a composition profile is formed, in which the Ge concentration is gradually increased toward the base region from a hetero-junction interface between the P-doped SiGe layer and the Si substrate of the collector region, the hetero-junction interface being as a starting point of the increase. The profile of the Ge concentration can prevent occurrence of a distortion due to a lattice mismatch on the hetero-junction interface in the collector region.

Note that, in the Si/SiGe-HBT according to the first embodiment, the Ge concentration is inclined in the base region to provide an acceleration effect to the carrier transit in the base region. Moreover, the Ge concentration increased in the P-doped SiGe layer is maintained at approximately the same level for a certain amount of depth in the B-doped Si/SiGe layer from the interface therebetween. When a composition distribution continuing in the above-described manner is formed, occurrence of a band gap barrier as an impediment to the carrier transit can be prevented, which is preferable.

Note that, in the emitter region, an n-type region is formed by doping As by a higher concentration than that of the B dopant similarly to the conventional.

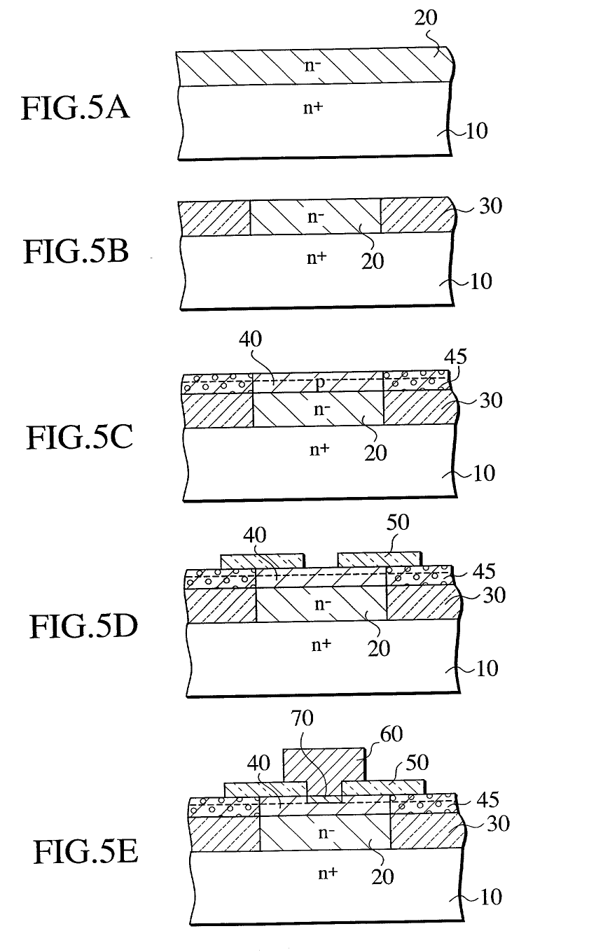

Next, description will be made for a method of manufacture of the Si/SiGe-HBT according to the first embodiment with reference to FIGS. 5A to 5E.

First, as shown in FIG. 5A, on the n⁺ Si layer 10 doped with the n⁻-type impurity by a high concentration, the n⁻-type SiGe epitaxial layer 20 doped with P by about 10¹⁶ to 10¹⁷/cm³ is subjected to epitaxial growth by an extent of 20 nm to 100 nm. As epitaxial growth conditions in this case, pressure is set in a range of about 1300 to 2000 Pa, and a substrate temperature is set in a range of about 650 to 750° C. Moreover, with regard to gas sources, SiH₄ is used as a Si material gas, and GeH₄ is used as a Ge material gas. Moreover, as an n-type impurity gas, PH₃ is mixed in a reaction gas. A gas flow ratio of the SiH₄ gas and the GeH₄ gas is set at 1:0 at the beginning of the film growth. Then, the Ge concentration in the film is adjusted so as to be gradually increased and then to finally reach a range of about 10 atm % to 20 atm %, preferably about 15 atm %, which is equal to the maximum Ge concentration in the base region. As a Si material gas, besides the above, a gas such as SiH₂Cl₂ and SiH₆ may be used.

Note that, the above step may be performed by a substrate supplier. In this case, steps below may be performed by a device manufacturer.

Next, as shown in FIG. 5B, the n⁻-type SiGe epitaxial layer 20 is removed by etching so as to leave the transistor-forming region, then the buried insulating film 30 is formed in a portion from which the n⁻-type SiGe epitaxial layer 20 is removed, thus the periphery thereof is isolatedly insulated.

Thereafter, as shown in FIG. 5C, on the substrate surface, formed is the p-type Si/SiGe epitaxial layer 40 doped with B by an extent of 10¹⁸ to 10¹⁹/cm³. As epitaxial growth conditions in this case, the pressure is set in a range of about 1300 to 2000 Pa, and the substrate temperature is set in a range of about 650 to 750° C. Moreover, with regard to the gas source, for example, as a Si material gas, SiH₄ is used, and GeH₄ is used as a Ge material gas. B₂H₆ is added thereto as an impurity gas. At the beginning of the film growth, the gas flow ratio of the SiH₄ gas and the GeH₄ gas is set at 10:4, and the Ge concentration in the film is adjusted so as to reach the range of about 10 atm % to 20 atm %, preferably 15 atm %. Thereafter, the gas flow ratio is gradually changed so that the Ge concentration can be adjusted to 0 atm % when the film thickness is grown to a range of about 30 nm to 100 nm, preferably to a range of about 50 to 60 nm. Thereafter, a Ge flow amount is set at zero, and the epitaxial layer is grown to have a film thickness of about 20 nm to 30 nm. Accordingly, the uppermost layer having a thickness of about 20 nm to 30 nm becomes a Si layer without Ge contained therein.

In this case, as shown in FIG. 5C, the polycrystal Si/SiGe layer 45 may be simultaneously formed on the exposed surface of the buried insulating film 30 by use of a nonselective growth method. The polycrystal Si/SiGe layer 45 can be used as a lead electrode of the base region.

Furthermore, as shown in FIG. 5D, the oxidation film 50 such as a SiO₂ film is formed on the substrate surface by use of a CVD method so as to have a thickness of about 50 to 100 nm. Thereafter, an opening is formed by use of anisotropic etching such as a reactive ion etching method. To the bottom of the opening, a surface of the p-type Si/SiGe epitaxial layer 40 is exposed. Note that, not only the anisotropic etching but also isotropic etching and a combination thereof may be used.

As shown in FIG. 5E, the n⁺-type polycrystal Si layer 60 having a thickness of about 200 nm is formed by use of the CVD method so as to bury the opening formed in the oxidation film 50. In this case, the n⁺-type polycrystal Si layer 60 is doped with arsenic (As) as an n-type impurity by 10²¹ to 10²²/cm³. For the doping of the impurity to the polycrystal Si layer 60, there may be employed a method for implanting the n-type impurity by ion implantation after a polycrystal undoped-Si layer is formed.

Thereafter, the Si/SiGe-HBT is subjected to heat treatment for about 10 to 30 seconds at a temperature ranging from 950 to 1050° C. By this heat treatment, the n-type impurity in the n⁺-type polycrystal Si layer 60 is diffused from the opening into the Si layer as the upper layer of the p-type Si/SiGe epitaxial layer 40, thus the n-type Si epitaxial region 70 having a depth of about 20 nm to 30 nm, that is, the emitter region is formed. Moreover, a final width of the base region is preferably set in a range of about 50 nm to 60 nm. Note that, the n⁺-type polycrystal Si layer 60 can be used as a lead electrode of the emitter region.

In the above-described method, the emitter region is formed by thermally diffusing As in the n⁺-type polycrystal Si layer 60. However, besides the thermal diffusion method, n-type impurity ions are implanted and diffused into the Si layer by a direct ion implantation method and the like, thus also the emitter region can be formed. Moreover, though P and the like other than As is usable as an impurity ion source, it is more advantageous to use ions having large atomic numbers in order to shallowly form a diffusion region.

### Second Embodiment

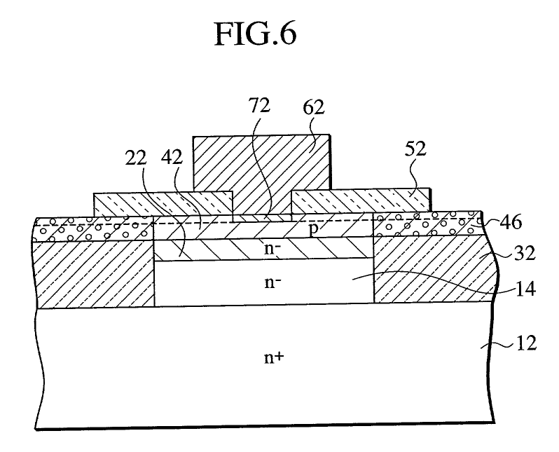

FIG. 6 is a sectional view showing a structure of a Si/SiGe-hetero-bipolar transistor according to a second embodiment of the present invention.

Usually, in many cases, an n⁺-type Si layer 12 and an n⁻-type Si layer 14 are already formed on a substrate supplied from a substrate manufacturer. In the case of using such a substrate, a structure of the hetero-bipolar transistor according to the second embodiment described herein may be used.

As shown in FIG. 6, an n⁻-type SiGe epitaxial layer 22 doped with an n-type impurity is formed on the n⁻-type Si epitaxial layer 14, and the n⁻-type Si epitaxial layer 14 and the n⁻-type SiGe epitaxial layer 22 are isolatedly insulated from the periphery thereof by a buried insulating film 32. On the n⁻-type SiGe epitaxial layer 22, formed is a p-type Si/SiGe epitaxial layer 42, in which an upper layer is Si and a lower layer is SiGe. And, a polycrystal Si/SiGe layer 46 is formed on the buried insulating film 32.

An oxidation film 52 having an opening in a center thereof is formed on the p-type Si/SiGe epitaxial layer 42, and an n⁺-type polycrystal Si layer 62 doped with an n-type impurity by a high concentration is formed so as to bury the opening, then the n-type impurity is thermally diffused from the n⁺-type polycrystal Si layer 62 into the Si layer as an upper layer of the p-type Si/SiGe epitaxial layer 42, thus an n-type Si epitaxial region 72 as an emitter region is formed.

In the Si/SiGe-HBT according to the second embodiment, a structure on and above the n⁻-type SiGe epitaxial layer 22 is common to that of the Si/SiGe-HBT of the first embodiment. Therefore, the composition profile in the depth direction in the center of the transistor is approximately the same as that of the first embodiment shown in FIG. 4. Accordingly, since the B-C junction position can be determined mainly by the diffusion condition of B similarly to the case of the first embodiment, the width of the base region can be adjusted to be narrower, thus enabling the acceleration of carriers. Moreover, the B concentration and the P concentration at the B-C junction position can be maintained to be relatively high, the expansion of the depletion layer can be suppressed. Consequently, the waste of the carrier transit time due to the depletion layer can be suppressed. Furthermore, the composition profile is formed, in which the Ge concentration is gradually increased toward the base region from the hetero-junction interface between the P-doped SiGe layer and the Si substrate. Therefore, the occurrence of the distortion due to the lattice mismatch on the hetero-junction interface in the collector region is prevented, thus the crystallinity of each epitaxial layer can be improved.

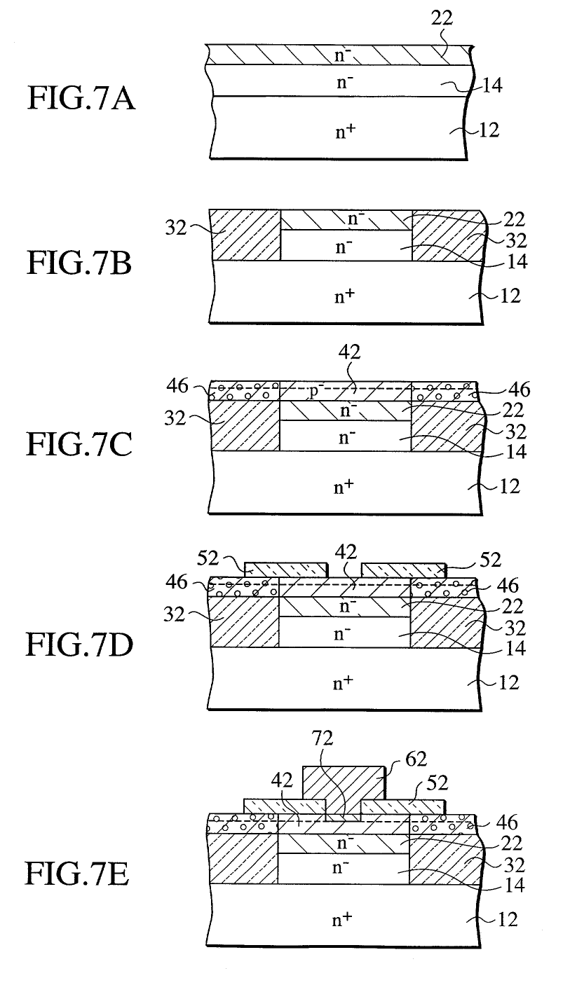

Next, description will be made for a method of manufacture of the Si/SiGe-HBT in the second embodiment with reference to FIGS. 7A to 7E.

First, as shown in FIG. 7A, the n⁻-type Si epitaxial layer 14 is formed on the n⁺-type Si layer 12 doped with the n-type impurity by a high concentration. Note that, in the case of obtaining a substrate in which the n⁺-type Si layer 12 and the n⁻-type Si epitaxial layer 14 are already formed, the manufacture of the Si/SiGe-HBT may be started from the next step of forming the n⁻-type SiGe epitaxial layer 22.

As a growth condition of the n⁻-type SiGe epitaxial layer 22, the same one as that of the first embodiment can be used. Also in this case, the flow ratio of the SiH₄ gas and the GeH₄ gas is changed with time and adjusted so as to gradually increase the Ge concentration after the beginning of the deposition.

As shown in FIG. 7B, the n⁻-type SiGe epitaxial layer 14 and the n⁻-type SiGe epitaxial layer 22 are removed by etching so as to leave the transistor-forming region, then an insulating film is buried in the portion from which the n⁻-type SiGe epitaxial layer 22 and the n⁻-type SiGe epitaxial layer 14 are removed, thus the buried insulating film 32 is formed. For subsequent steps, the same conditions as those in the method according to the first embodiment can be basically used.

As shown in FIG. 7C, the p-type Si/SiGe epitaxial layer 42 is formed on the surfaces of the n⁻-type SiGe epitaxial layer 22 and the buried insulating film 32. As epitaxial growth conditions in this case, the same conditions as those in the method according to the first embodiment can be used. At the beginning of the film growth, adjustment is performed so that the Ge concentration of the n⁻-type SiGe epitaxial layer 22 and the Ge concentration of the p-type Si/SiGe epitaxial layer 42 can be equal to each other. When a film thickness of the p-type Si/SiGe epitaxial layer 42 reaches a range of about 30 nm to 100 nm, preferably 50 nm, the gas flow ratio is adjusted with time so that the Ge concentration can be 0 atm %. The Ge gas flow amount is set at zero, and a Si layer having a thickness of about 20 nm to 30 nm without Ge contained therein is formed as the upper layer of the p-type Si/SiGe epitaxial layer 42.

Note that, since the n⁻-type SiGe epitaxial layer 22 and the p-type Si/SiGe epitaxial layer 42 have different conduction types from each other, here, each of the layers may be subjected to the epitaxial growth in a separate chamber from the other in order to prevent contamination in the chamber.

Moreover, at this time, the polycrystal Si/SiGe layer 46 may be simultaneously formed on the exposed surface of the buried insulating film 32.

Furthermore, as shown in FIG. 7D, the oxidation film 52 is formed on the substrate surface by use of the CVD method. Thereafter, an opening is formed by use of dry etching. To the bottom of the opening, a surface of the p-type Si/SiGe epitaxial layer 42 is exposed.

As shown in FIG. 7E, the n⁺-type polycrystal Si layer 62 doped with arsenic (As) as an n-type impurity is formed by use of the CVD method so as to bury the opening formed in the oxidation film 52. Then, the n-type impurity in the n⁺-type polycrystal Si layer 62 is thermally diffused from the opening into the Si layer as the upper layer of the p-type Si/SiGe epitaxial layer 42, thus the n-type Si epitaxial region 72, that is, the emitter region is formed.

### Third Embodiment

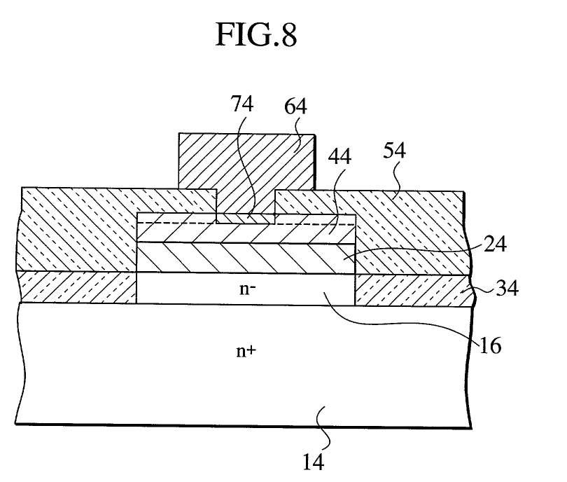

FIG. 8 is a sectional view showing a structure of a Si/SiGe-HBT according to a third embodiment of the present invention.

As shown in FIG. 8, an n⁻-type Si epitaxial layer 16 is formed on an n⁺-type Si layer 14 similarly to the conventional. On the periphery of sidewalls of the n⁻-type Si epitaxial layer 16, a buried insulating film 34 is formed so as to define the transistor-forming region, and the n⁻-type Si epitaxial layer 16 is isolatedly insulated from the periphery thereof by the buried insulating film 34.

The Si/SiGe-HBT according to the third embodiment is different from that of the second embodiment in the following point. Specifically, in the third embodiment, an n⁻-type SiGe epitaxial layer 24 and a p-type Si/SiGe epitaxial layer 44 are formed on the n⁻-type Si epitaxial layer 16 in a laminated manner by use of a continuous epitaxial growth step in the same chamber. Here, an example is shown, where the n⁻-type SiGe epitaxial layer 24 and the p-type Si/SiGe epitaxial layer 44 are selectively grown only on the n⁻-type Si epitaxial layer 16. However, as basic growth conditions for each layer, the same ones as those in the first and second embodiments may be used.

In an insulating film 54 formed so as to cover the laminated film, an opening is formed in a center thereof, and an n⁺-type polycrystal Si layer 64 doped with an n-type impurity by a high concentration is formed so as to bury the opening, then the n-type impurity is thermally diffused from the n⁺-type polycrystal Si layer 64 into a surface layer of the p-type Si/SiGe epitaxial layer 44, thus an n-type Si epitaxial region 74 as an emitter region is formed.

In the Si/SiGe-HBT according to the third embodiment, a structure on and above the n⁻-type SiGe epitaxial layer 24 is common to those of the HBT of the first and second embodiments. Accordingly, the composition profile in the depth direction in the center of the transistor is approximately the same as that of the first embodiment shown in FIG. 4. Therefore, since the B-C junction position can be determined mainly by the diffusion condition of B similarly to the cases of the first and second embodiments, the width of the base region can be adjusted to be narrower, thus enabling the acceleration of carriers. Moreover, since the carrier concentration in the vicinity of the B-C junction position can be maintained to be relatively high, the expansion of the depletion layer is suppressed, and thus an effective base width can be narrowed. Furthermore, the composition profile is formed, in which the Ge concentration is gradually increased toward the base region from the hetero-junction interface between the P-doped SiGe layer and the Si substrate. Therefore, the occurrence of the distortion due to the lattice mismatch on the hetero-junction interface in the collector region is prevented, thus the crystallinity of each epitaxial layer can be improved.

As described above, the semiconductor device of this embodiment comprises: a first-conductive-type Si semiconductor substrate layer; a first Si₁₋ₓGeₓ layer (0<x<1) formed on the first-conductive-type Si semiconductor substrate, the first Si₁₋ₓGeₓ layer being doped with a first-conductive-type impurity approximately evenly in a depth direction thereof; a second Si₁₋ₓGeₓ layer formed on the first Si₁₋ₓGeₓ layer, the second Si₁₋ₓGeₓ layer being doped with a second-conductive-type impurity; and a Si layer formed on the second Si₁₋ₓGeₓ layer, the Si layer being doped with the first-conductive-type impurity by a concentration higher than that of the second-conductive-type impurity.

Therefore, formed is the hetero-bipolar transistor (HBT) having the collector region in the first Si₁₋ₓGeₓ layer, the base region in the second Si₁₋ₓGeₓ layer, and the emitter region in the Si layer. Moreover, it is made possible to determine the junction (B-C junction) position between the base region and the collector region only by the adjustment of the diffusion conditions of the second-conductive-type impurity diffusing mainly from the base region toward the collector region. Therefore, it is easier to make the base region width narrower. Moreover, since the impurity with a specified concentration or more can be secured in the vicinity of the B-C junction position, the expansion of the depletion layer width of the junction portion can be suppressed. Accordingly, the transit time of the carriers consumed in the depletion layer is shortened, thus the acceleration of the carrier action speed can be achieved.

Moreover, suppose that the concentration of the first-conductive-type impurity contained in the first Si₁₋ₓGeₓ layer is set lower than that of the second-conductive-type impurity contained in the second Si₁₋ₓGeₓ layer. Then, it is made more securely possible to adjust the B-C junction position only by the diffusion conditions of the second-conductive-type impurity diffusing from the base region toward the collector region. Moreover, the impurity concentration in the collector region is suppressed to be lower than in the base region, and thus the depletion layer is expanded mainly toward the collector region. Thereby, the thin base region layer is depleted and punched through, thus the transistor can be prevented from being broken down. Accordingly, a substantial pressure resistance of the transistor can be enhanced.

Furthermore, if the second Si₁₋ₓGeₓ layer forms the composition distribution in the depth direction, in which the Ge concentration is gradually reduced in the direction of the Si layer, then suppressed is the occurrence of the distortion due to the lattice mismatch on the hetero interface between the first Si₁₋ₓGeₓ layer and the first-conductive-type Si semiconductor substrate, thus a margin for the misfit transition can be increased.

Moreover, in the case where the Ge concentrations in the first and second Si₁₋ₓGeₓ layers are set approximately equal to each other on the boundary therebetween, the occurrence of the distortion due to the lattice mismatch on the boundary portion between the first Si₁₋ₓGeₓ layer and the first-conductive-type Si semiconductor substrate can be also suppressed.

Furthermore, in the case where the second Si₁₋ₓGeₓ layer has a concentration distribution in the depth direction, in which the Ge concentration is gradually increased toward the first Si₁₋ₓGeₓ layer from the interface between the second Si₁₋ₓGeₓ layer and the Si layer taken as a starting point of the increase, the band gap inclination is formed in the base region from the emitter region toward the collector region, thus the effect of accelerating the carrier transit in the base region is obtained.

Meanwhile, the method of manufacture of a semiconductor device of this embodiment comprises: preparing a substrate on a first-conductive-type Si semiconductor substrate layer, the substrate having a first Si₁₋ₓGeₓ layer doped with a first-conductive-type impurity; forming a second Si₁₋ₓGeₓ layer and a Si layer on the first Si₁₋ₓGeₓ layer in a laminated manner, the second Si₁₋ₓGeₓ layer being doped with a second-conductive-type impurity approximately evenly in a depth direction thereof; forming an insulating film having an opening on the Si layer; and doping the first-conductive-type impurity to the Si layer through the opening by a concentration higher than that of the second-conductive-type impurity.

Therefore, it is possible to form the hetero-bipolar transistor (HBT) having the collector region in the first Si₁₋ₓGeₓ layer, the base region in the second Si₁₋ₓGeₓ layer, and the emitter region in the Si layer. In this HBT, since the first-conductive-type impurity is doped to the first Si₁₋ₓGeₓ layer forming the collector region, it is made possible to adjust the B-C junction position only by the diffusion conditions of the second-conductive-type impurity from the base region toward the collector region. Accordingly, the adjustment for narrowing the base region width can be further facilitated.

In the case of forming the first Si₁₋ₓGeₓ layer by the epitaxial growth method, the flow ratio of the Ge material gas to the Si material gas is gradually increased from the beginning of the growth, thus making it possible to form the concentration gradient in which the Ge concentration is gradually reduced toward the Si semiconductor substrate layer. Accordingly, suppressed is the occurrence of the distortion due to the lattice mismatch on the hetero interface between the first Si₁₋ₓGeₓ layer and the Si layer, thus the margin for the misfit transit can be increased.

Note that, the second Si₁₋ₓGeₓ layer and the Si layer may be formed in the same chamber by a continuous epitaxial growth method. In this case, some steps can be omitted.

Moreover, the first Si₁₋ₓGeₓ layer and the second Si₁₋ₓGeₓ layer may be formed by the epitaxial growth method by use of separate chambers, respectively. In this case, the Si₁₋ₓGeₓ layers are formed by use of different chambers, each layer having an impurity of a conductive type different from the other. Thus, the contamination in the chamber is prevented, and an adjustment accuracy of the impurity concentration can be improved.

Alternatively, the first Si₁₋ₓGeₓ layer, the second Si₁₋ₓGeₓ layer, and the Si layer may be formed in the same chamber by the continuous epitaxial growth method. In this case, the above-described layers are formed in the same chamber by use of the continuous epitaxial growth method, thus omission of the steps can be achieved to a great extent.

Moreover, when the second Si₁₋ₓGeₓ layer is subjected to the epitaxial growth, adjustment may be made so as to gradually reduce the flow ratio of the Ge material gas to the Si material gas. In this case, the Ge concentration is gradually increased in the base region from the emitter region toward the collector region, and the band gap inclination is formed, thus the effect of accelerating the carrier transit in the base region can be obtained.

As above, description has been made for the structure of the hetero-bipolar transistor of the present invention and the method of manufacture thereof. However, the present invention is not limited to the description of these embodiments. For example, in the above-described embodiments, the concentration of the impurity doped into the collector region is set approximately constant in the depth direction thereof. However, the impurity concentration may be set higher toward a deeper orientation. In this case, effects are obtained, in which the expansion of the depletion layer unnecessarily extending to the collector side is suppressed and the collector resistance is lowered. It is apparent to those skilled in the art that other various alterations and modifications are enabled. For example, in each of the above-described embodiments, the npn-type hetero-bipolar transistor has been exemplified. However, even if the conduction type of each region is replaced with an inversed conduction type, the effect of the invention of this application is effective. Moreover, with regard to types of the impurities, each imparting the conduction type to each layer, various gas sources can be used besides the gas sources enumerated in the above-described embodiments.

As described above, in the Si/SiGe-HBT according to this embodiment, the composition profile in the depth direction can be optimized, and good crystallinity with less distortion can be provided on the hetero interface in the collector region. Therefore, the acceleration of operational speed of the HBT can be achieved. Accordingly, the Si/SiGe-HBT can be applied to various purposes such as a main frame of a super computer for which a high-speed operation and a high-frequency operation are required and various types of radio equipment used at a high frequency band.

What is claimed is:

1. A semiconductor device, comprising:
a first-conductive-type Si semiconductor substrate layer;
a first Si₁₋ₓGeₓ layer (0<x<1) formed on the first-conductive-type Si semiconductor substrate, the first Si₁₋ₓGeₓ layer being doped with a first-conductive-type impurity approximately evenly in a depth direction thereof;
a second Si₁₋ₓGeₓ layer (0<x<1) formed on the first Si₁₋ₓGeₓ layer, the second Si₁₋ₓGeₓ layer being doped with a second-conductive-type impurity; and
a Si layer formed on the second Si₁₋ₓGeₓ layer, the Si layer being doped with the first-conductive-type impurity by a concentration higher than a concentration of the second-conductive-type impurity.

2. The semiconductor device of claim 1,
wherein the concentration of the first-conductive-type impurity contained in the first Si₁₋ₓGeₓ layer is lower than the concentration of the second-conductive-type impurity contained in the second Si₁₋ₓGeₓ layer.

3. The semiconductor device of claim 1,
wherein the first Si₁₋ₓGeₓ layer has a concentration distribution in a depth direction thereof, the concentration distribution having a Ge concentration gradually increased toward the second Si₁₋ₓGeₓ layer from an interface between the first Si₁₋ₓGeₓ layer and the Si semiconductor substrate layer, the interface being as a starting point of the increase.

4. The semiconductor device of claim 1,
wherein the first Si₁₋ₓGeₓ layer and the second Si₁₋ₓGeₓ layer have Ge concentrations approximately equal to each other in the vicinity of a boundary therebetween.

5. The semiconductor device of claim 1,
wherein the second Si₁₋ₓGeₓ layer has a concentration distribution in a depth direction thereof, the concentration distribution having the Ge concentration gradually increased toward the first Si₁₋ₓGeₓ layer from an interface between the second Si₁₋ₓGeₓ layer and the Si layer, the interface being as a starting point of the increase.

6. The semiconductor device of claim 2,
wherein the first Si₁₋ₓGeₓ layer has the concentration distribution in the depth direction thereof, the concentration distribution having the Ge concentration gradually increased toward the second Si₁₋ₓGeₓ layer from the interface between the first Si₁₋ₓGeₓ layer and the first Si semiconductor substrate layer, the interface being as the starting point of the increase.

7. The semiconductor device of claim 2,
wherein the first Si₁₋ₓGeₓ layer and the second Si₁₋ₓGeₓ layer have the Ge concentrations approximately equal to each other in the vicinity of the boundary therebetween.

8. The semiconductor device of claim 2,
wherein the second Si₁₋ₓGeₓ layer has the concentration distribution in the depth direction thereof, the concentration distribution having the Ge concentration gradually increased toward the first Si₁₋ₓGeₓ layer from the interface between the second Si₁₋ₓGeₓ layer and the Si layer, the interface being as the starting point of the increase.

9. The semiconductor device of claim 3,
wherein the first Si₁₋ₓGeₓ layer and the second Si₁₋ₓGeₓ layer have the Ge concentrations approximately equal to each other in the vicinity of the boundary therebetween.

10. The semiconductor device of claim 3,
wherein the second Si₁₋ₓGeₓ layer has the concentration distribution in the depth direction thereof, the concentration distribution having the Ge concentration gradually increased toward the first Si₁₋ₓGeₓ layer from the interface between the second Si₁₋ₓGeₓ layer and the Si layer, the interface being as the starting point of the increase.

11. The semiconductor device of claim 4,
wherein the second Si₁₋ₓGeₓ layer has the concentration distribution in the depth direction thereof, the concentration distribution having the Ge concentration gradually increased toward the first Si₁₋ₓGeₓ layer from the interface between the second Si₁₋ₓGeₓ layer and the Si layer, the interface being as the starting point of the increase.

12. A method of manufacturing a semiconductor device, comprising:
preparing a substrate having a first-conductive-type Si semiconductor substrate layer and a first Si₁₋ₓGeₓ layer formed on the first-conductive-type Si semiconductor substrate layer, the first Si₁₋ₓGeₓ layer doped with a first-conductive-type impurity approximately evenly in a depth direction thereof;
forming a second Si₁₋ₓGeₓ layer and a Si layer on the first Si₁₋ₓGeₓ layer in a laminated manner, the second Si₁₋ₓGeₓ layer being doped with a second-conductive-type impurity;
forming an insulating film having an opening on the Si layer; and
doping the first-conductive-type impurity to the Si layer through the opening by a concentration higher than a concentration of the second-conductive-type impurity.

13. The method of claim 12,
wherein the preparing the substrate comprises forming the first Si₁₋ₓGeₓ layer on the first-conductive-type Si semiconductor substrate layer by using an epitaxial growth process.

14. The method of claim 12,
wherein the forming the second Si₁₋ₓGeₓ layer and the Si layer are performed by an epitaxial growth process in a same chamber.

15. The method of claim 12,
wherein the forming the second Si₁₋ₓGeₓ layer comprises gradually reducing a flow ratio of a Ge material gas to a Si material gas.

16. The method of claim 13,
wherein the forming the first Si₁₋ₓGeₓ layer comprises gradually increasing the flow ratio of the Ge material gas to the Si material gas from the beginning of the growth.

17. The method of claim 13,
wherein the forming the first Si₁₋ₓGeₓ layer and the second Si₁₋ₓGeₓ layer are performed by an epitaxial growth process using separate chambers, respectively.

18. The method of claim 13,
wherein the forming the first Si₁₋ₓGeₓ layer and the forming the second Si₁₋ₓGeₓ layer and the Si layer are performed by a continuous epitaxial growth process in a same chamber.

19. The method of claim 13,
wherein the forming the second Si₁₋ₓGeₓ layer and the Si layer in the laminated manner is performed by a continuous epitaxial growth step in a same chamber.

20. The method of claim 13,
wherein the forming the second Si₁₋ₓGeₓ layer comprises gradually reducing a flow ratio of a Ge material gas to a Si material gas.
